(19) United States
(12) Patent Application Publication
(10) Pub. No.: US 2019/0189497 A1
(43) Pub. Date: Jun. 20, 2019

(54) WORKPIECE PROCESSING METHOD

(71) Applicant: DISCO CORPORATION, Tokyo (JP)

(72) Inventor: Kazuma SEKIYA, Tokyo (JP)

(21) Appl. No.: 16/215,735

(22) Filed: Dec. 11, 2018

(30) Foreign Application Priority Data
Dec. 18, 2017 (JP) 2017-241869

(51) Int. Cl. H01L 21/687; H01L 21/683; H01L 21/78

(52) U.S. Cl. CPC H01L 21/68721; H01L 21/6836; H01L 21/67092; H01L 21/78; H01L 2221/68327; H01L 21/68735

(57) ABSTRACT

A workpiece processing method includes: a workpiece fixing step of fixing a workpiece to a sheet larger than the workpiece by a close contact force acting between the workpiece and the sheet; a frame preparing step of preparing a frame including an annular portion having an opening of a diameter larger than the workpiece and smaller than the sheet and a pressing portion having an opening of a diameter larger than the workpiece and smaller than the sheet; a sheet fixing step of fixing the sheet to the frame by sandwiching an outer circumferential portion of the sheet by the annular portion and the pressing portion; and a processing step of processing the workpiece.

### BACKGROUND OF THE INVENTION

### Field of the Invention

The present invention relates to a processing method of processing a workpiece.

### Description of the Related Art

In a device chip manufacturing process, a plurality of intersecting planned dividing lines (streets) are set on a top surface of a semiconductor wafer or a substrate such as a package substrate, a ceramic substrate, a glass substrate, or the like, and devices are arranged in respective regions demarcated by the planned dividing lines. When the substrate provided with the devices is divided along the planned dividing lines, individual device chips are formed. Used to divide the substrate is for example a cutting apparatus having a cutting blade capable of cutting the substrate along the planned dividing lines or a processing apparatus such as a laser processing apparatus capable of forming a laser-processed groove or an internal modified layer by irradiating the substrate with a laser beam along the planned dividing lines or the like. Before a workpiece such as the substrate or the like is carried into the processing apparatus, a frame unit is formed by affixing a dicing tape stretched over an opening of an annular frame to the workpiece in advance. The dicing tape has an adhesive surface having stickiness, and is affixed to the frame and the workpiece by the adhesive force of the adhesive surface.

The workpiece is carried into the processing apparatus and processed in a state of the frame unit. Each individual device chip formed by dividing the workpiece by the processing is retained by the dicing tape, and picked up from the frame unit. When the device chip is picked up, intervals between individual device chips are widened by expanding the dicing tape to facilitate pickup work. The dicing tape includes an adhesive layer having an adhesive surface and a substrate layer supporting the adhesive layer, and is configured to enable easy peeling of the formed device chips while appropriately holding the workpiece during the processing. Such a high-performance dicing tape is expensive. Moreover, the dicing tape is a consumable article discarded after one-time usage. The cost of the dicing tape therefore greatly affects the manufacturing cost of the device chips. In addition, after the device chips are peeled off the dicing tape, a part of the adhesive layer may remain as a residue on the device chips, and cause a defect in the device chips. Further, when the dicing tape is peeled off the annular frame, a part of the adhesive layer similarly remains as a residue on the frame. The frame therefore needs to be cleaned when the frame is reused.

Accordingly, in place of the dicing tape affixed to the workpiece by the adhesive force of the adhesive layer, a sheet has been proposed which does not have an adhesive layer but is fixed to the workpiece by a tack force, a van der Waals force, or the like (see Japanese Patent Laid-Open No. 2013-247136).

### SUMMARY OF THE INVENTION

When a sheet not having any adhesive layer is used, the adhesive layer does not remain on the device chips or the frame. On the other hand, steps are necessary which prepare an adhesive for fixing the sheet to the frame, and fix the sheet to the frame by the adhesive. In a case where the sheet is fixed to the frame by using the adhesive, the adhesive involves a cost, and a bonded surface of the frame still needs to be cleaned. The present invention has been made in view of such problems. It is an object of the present invention to provide a processing method that can fix a sheet to a frame without the use of an adhesive or the like, and obviates a need for frame cleaning work after the sheet and the frame are separated from each other.

In accordance with an aspect of the present invention, there is provided a workpiece processing method including: a workpiece fixing step of fixing a workpiece to a sheet larger than the workpiece by a close contact force acting between the workpiece and the sheet; a frame preparing step of preparing a frame including an annular portion having an opening of a diameter larger than the workpiece and smaller than the sheet and a pressing portion having an opening of a diameter larger than the workpiece and smaller than the sheet; a sheet fixing step of fixing the sheet to the frame by sandwiching an outer circumferential portion of the sheet by the annular portion and the pressing portion after the frame preparing step and before or after the workpiece fixing step; and a processing step of processing the workpiece after the workpiece fixing step and the sheet fixing step are performed.

Preferably, the frame has a magnet in the annular portion or the pressing portion, and in the sheet fixing step, the sheet is sandwiched by a magnetic force acting between the annular portion and the pressing portion.

In addition, preferably, the pressing portion has an outside diameter to fit into the opening of the annular portion, and in the sheet fixing step, the pressing portion is fitted into the opening of the annular portion, and the sheet is sandwiched between an inner peripheral wall of the opening of the annular portion and an outer peripheral wall of the pressing portion.

In addition, preferably, the frame further includes a fixing member, and in the sheet fixing step, the annular portion and the pressing portion sandwiching the sheet are fixed by the fixing member.

The processing method according to one mode of the present invention performs the workpiece fixing step of fixing the workpiece to the sheet and the sheet fixing step of fixing the sheet to the frame before performing the processing step of processing the workpiece. In the sheet fixing step, because the frame has the annular portion and the pressing portion having an opening of a diameter larger than the workpiece and smaller than the sheet, the sheet can be fixed to the frame by sandwiching the outer circumferential portion of the sheet by the annular portion and the pressing portion. The adhesive for fixing the sheet to the frame therefore becomes unnecessary. In addition, the sheet can be separated from the frame by releasing the sandwiching by the annular portion and the pressing portion. Thus, the adhesive or the like does not adhere to the frame, so that the cleaning of the frame is rendered unnecessary. Hence, the present invention provides a processing method that can fix the sheet to the frame without the use of any adhesive or the like, and obviates a need for frame cleaning work after the sheet and the frame are separated from each other.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting a workpiece;

FIG. 2A is a perspective view schematically depicting a frame preparing step and a sheet fixing step;

FIG. 2B is a perspective view schematically depicting a sheet fixed to a frame;

FIG. 3A is a perspective view schematically depicting the frame preparing step and the sheet fixing step;

FIG. 3B is a perspective view schematically depicting a sheet fixed to a frame;

FIG. 4A is a perspective view schematically depicting an example of the sheet fixing step;

FIG. 4B is a perspective view schematically depicting another example of the sheet fixing step;

FIG. 5 is a sectional view schematically depicting a workpiece fixing step;

FIG. 6A is a sectional view schematically depicting a manner in which a frame unit is placed onto a table; and

FIG. 6B is a sectional view schematically depicting a processing step.

### DETAILED DESCRIPTION OF THE PREFERRED EMBODIMENT

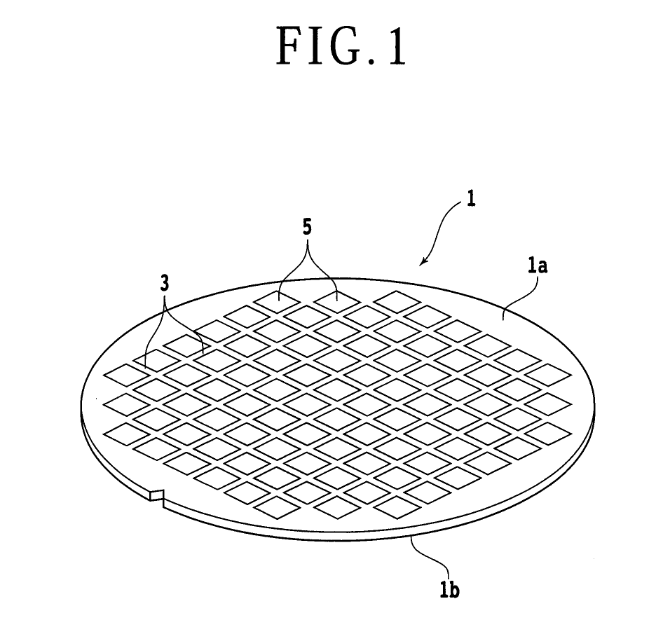

An embodiment according to one mode of the present invention will be described with reference to the accompanying drawings. A workpiece to be processed by a processing method according to the present embodiment will first be described with reference to FIG. 1. A workpiece 1 is for example a substrate formed of a material such as silicon, silicon carbide (SiC), another semiconductor, or the like, or a material such as sapphire, glass, quartz, ceramic, or the like. Alternatively, the workpiece 1 is a package substrate having devices covered with a resin. A plurality of intersecting planned dividing lines 3 are set on a top surface 1a of the workpiece 1. Devices 5 such as integrated circuits (ICs), large scale integrations (LSIs), or the like are arranged in respective regions demarcated by the planned dividing lines 3. Each individual device chip can be formed by dividing the workpiece 1 along the planned dividing lines 3.

In the processing method according to the present embodiment, a frame unit is formed by performing a sheet fixing step of fixing a sheet to an annular frame and a workpiece fixing step of fixing the workpiece 1 to the sheet. The workpiece is carried into a processing apparatus in a state of the frame unit, and is processed in a processing step. Each individual device chip formed by dividing the workpiece by the processing is retained by the sheet, and is picked up from the frame unit. Used to divide the workpiece 1 is for example a cutting apparatus having a cutting blade capable of cutting the workpiece 1 or a processing apparatus such as a laser processing apparatus capable of forming a laser-processed groove or an internal modified layer by irradiating the workpiece 1 with a laser beam or the like. Each step of the processing method according to the present embodiment will be described in the following.

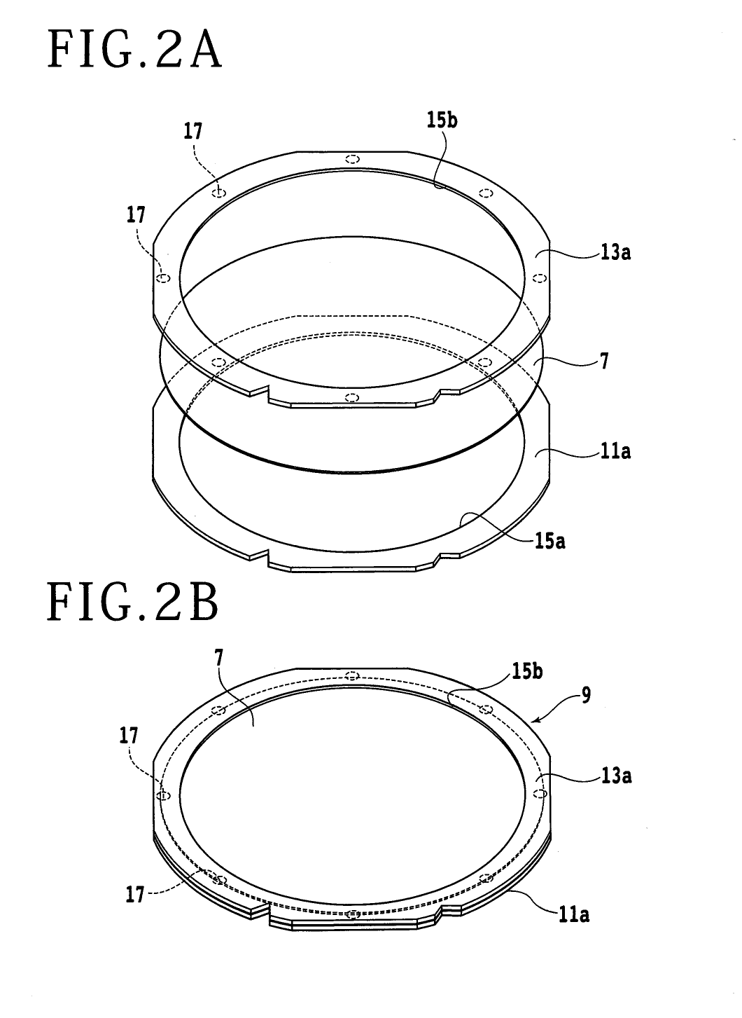

A frame preparing step and a frame fixing step will first be described with reference to FIG. 2A and FIG. 2B. FIG. 2A is a perspective view schematically depicting the frame preparing step and the sheet fixing step. The processing method according to the present embodiment uses a frame 9 including an annular portion 11a having an opening 15a of a smaller diameter than the sheet 7 to which the workpiece 1 is fixed and a pressing portion 13a having an opening 15b of a smaller diameter than the sheet 7. In the frame preparing step, the annular portion 11a and the pressing portion 13a are prepared. The annular portion 11a and the pressing portion 13a of the frame 9 are for example formed of a metal.

The sheet fixing step is performed after the frame preparing step. The sheet 7 is formed by for example an organic resin such as polyolefin, polyethylene, polypropylene, polyvinyl chloride, polyvinylidene chloride, or the like. The sheet 7 is formed by a member capable of being expanded by an external force. In the processing method according to the present embodiment, the sheet 7 larger than the workpiece 1 is used to hold the workpiece 1 and form the frame unit together with the frame 9. The sheet 7 does not have a bonding layer, but can fix the workpiece 1 thereto by a tack force, a van der Waals force, an electrostatic force, or the like. In addition, the workpiece 1 may be brought into close contact with the sheet 7 in a state in which a tensile force is acting on the sheet 7, and the workpiece 1 may be able to be fixed to the sheet 7 by reducing pressure between the workpiece 1 and the sheet 7.

As depicted in FIG. 2A, in the sheet fixing step, the sheet 7 is disposed between the annular portion 11a and the pressing portion 13a, and an outer circumferential portion of the sheet 7 is sandwiched by the annular portion 11a and the pressing portion 13a. Then, as depicted in FIG. 2B, the sheet 7 is fixed to the frame 9. Incidentally, because the opening 15a of the annular portion 11a and the opening 15b of the pressing portion 13a have a smaller diameter than the sheet 7, the opening 15a and the opening 15b are closed by the sheet 7, as depicted in FIG. 2A and FIG. 2B. As depicted in FIG. 2A and FIG. 2B, for example, the frame 9 has magnets 17 in at least one of the annular portion 11a and the pressing portion 13a. The magnets 17 have a function of generating a force that brings the annular portion 11a and the pressing portion 13a close to each other by a magnetic force acting between the annular portion 11a and the pressing portion 13a. In the sheet fixing step, the magnetic force generated by the magnets 17 is a source of a force for sandwiching the sheet 7.

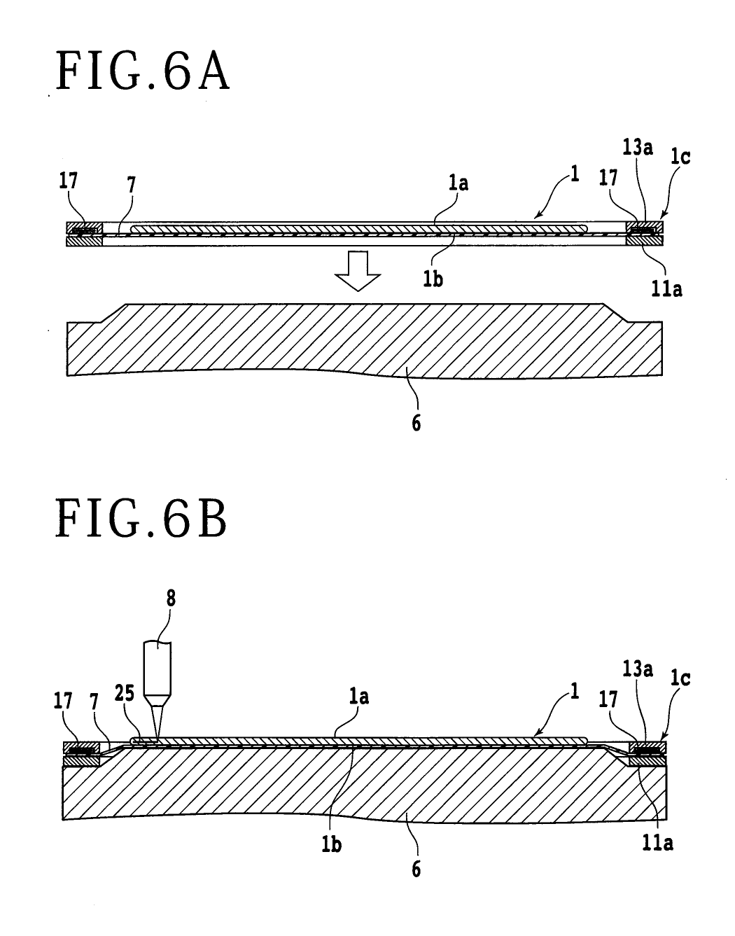

When the frame 9 is carried onto a table 6 (see FIG. 6A) of the processing apparatus, the frame 9 may be gripped by clamps (not depicted) provided around an outer circumferential portion of the table 6. The magnets 17 may be arranged at positions different from positions of contact between the clamps and the frame 9 so as not to hinder the gripping of the frame 9 by the clamps at this time. In addition, the magnets 17 may be arranged at the contact positions to strengthen the force of gripping the frame by the clamps.

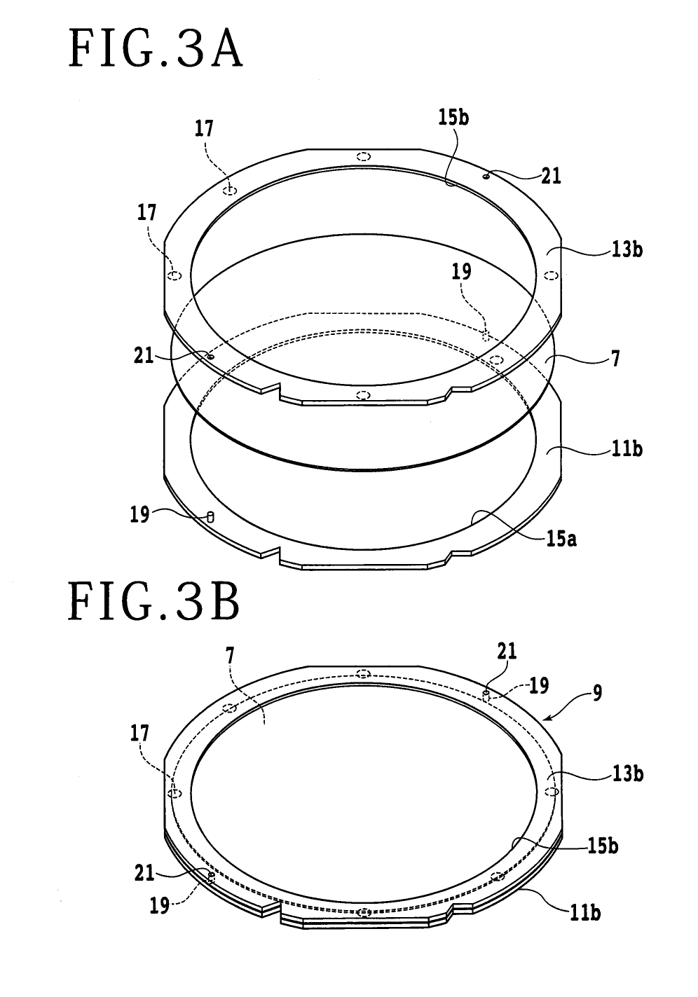

In addition, one of the annular portion and the pressing portion of the frame 9 may have pins (projecting portions) on a surface thereof facing the other of the annular portion and the pressing portion. In this case, the other of the annular portion and the pressing portion is provided with pin fitting holes at positions facing the pins. FIG. 3A and FIG. 3B illustrate a frame 9 having pins 19 on an annular portion 11b and having pin fitting holes 21 in a pressing portion 13b and a sheet 7 sandwiched by the frame 9. As depicted in FIG. 3A and FIG. 3B, the pins 19 and the pin fitting holes 21 are for example each arranged at a position outward of the sheet 7 sandwiched by the annular portion 11b and the pressing portion 13b. In this case, in the sheet fixing step, the sheet 7 is placed on the annular portion 11b so as to be surrounded by the pins 19, and is thereafter sandwiched by the annular portion 11b and the pressing portion 13b.

When the sheet 7 is sandwiched by the annular portion 11b and the pressing portion 13b, the pins 19 are fitted into the pin fitting holes 21. Then, the annular portion 11b and the pressing portion 13b are not easily displaced from each other even when an external force directed in a direction included in a plane perpendicular to the projecting direction of the pins 19 is applied to the annular portion 11b and the pressing portion 13b. Incidentally, the pins 19 and the pin fitting holes 21 may each be disposed at a position inward of an outer peripheral edge of the sheet 7. In this case, the sheet 7 sandwiched by the annular portion 11b and the pressing portion 13b is put into the pin fitting holes 21 by the pins 19. Then, the sheet 7 is sandwiched more strongly by the annular portion 11b and the pressing portion 13b, and movement such as rotation of the sheet 7 or the like is suppressed more.

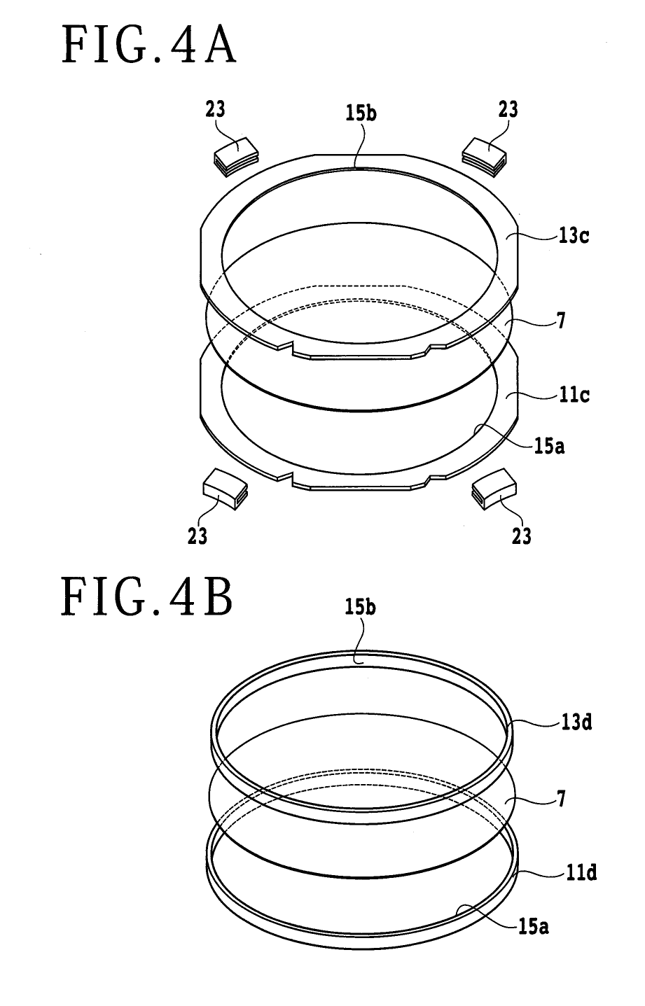

In the sheet fixing step, the sheet 7 may be sandwiched between the annular portion and the pressing portion by another method. A modification of the frame preparing step and the sheet fixing step will next be described with reference to FIG. 4A and FIG. 4B. An annular portion 11c and a pressing portion 13c depicted in FIG. 4A do not have magnets, but the sheet 7 may for example be sandwiched by fixing the annular portion 11c and the pressing portion 13c by a plurality of fixing members 23 that fix the annular portion 11c and the pressing portion 13c in a state of sandwiching the sheet 7. The fixing members 23 depicted in FIG. 4A are a member having a groove formed therein which has a width corresponding to a sum of thicknesses of the annular portion 11c, the pressing portion 13c, and the sheet 7. The annular portion 11c and the pressing portion 13c sandwiching the sheet 7 are fixed by being inserted into the groove. In this case, members having an identical shape and identical properties may be used as the annular portion 11c and the pressing portion 13c.

In addition, a pressing portion 13d depicted in FIG. 4B has such an outside diameter as to fit into an opening 15a of an annular portion 11d. When the sheet 7 is to be sandwiched by the annular portion 11d and the pressing portion 13d, the sheet 7 is placed on the annular portion 11d, and thereafter the pressing portion 13d is fitted into the opening 15a of the annular portion 11d from above. Then, the sheet 7 is sandwiched between an inner peripheral wall of the opening 15a of the annular portion 11d and an outer peripheral wall of the pressing portion 13d. In this case, the frame 9 does not need to have magnets, nor is a member such as a fixing member or the like necessary. Incidentally, in the case where the frame having the annular portion 11d and the pressing portion 13d depicted in FIG. 4B is used, the sheet 7 may be placed on the pressing portion 13d, and thereafter the pressing portion 13d may be fitted into the opening 15a of the annular portion 11d by lowering the annular portion 11d from above the pressing portion 13d. As described above, the sheet 7 is fixed to the frame 9 after the frame preparing step and the sheet fixing step are performed.

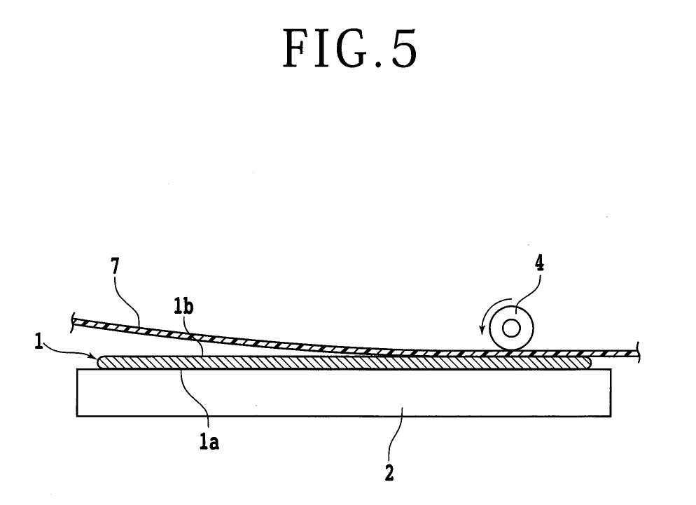

The workpiece fixing step in the processing method according to the present embodiment will next be described. The workpiece fixing step is performed before or after the sheet fixing step. In the workpiece fixing step, the workpiece 1 is fixed to the sheet 7. FIG. 5 is a sectional view schematically depicting the workpiece fixing step performed before the sheet fixing step. In the workpiece fixing step, the sheet 7 is brought into contact with a surface of the workpiece 1 which surface is on an opposite side from a surface to be processed of the workpiece 1 so as to expose the surface to be processed. In a case where the workpiece 1 is processed from the top surface 1a side, for example, the sheet 7 is fixed to an undersurface 1b side. In this case, for example, the workpiece 1 is placed on a flat table 2 in a state in which the undersurface 1b side is oriented upward, and the sheet 7 is brought into contact with the undersurface 1b side of the workpiece 1. Then, the sheet 7 is pressed from above by using a pressing roller 4, for example. Then, the workpiece 1 is fixed to the sheet 7.

Incidentally, in the workpiece fixing step, when the workpiece 1 is fixed to the sheet 7, the sheet 7 may be softened by heating the sheet 7 in advance. When the workpiece 1 is brought into contact with the softened sheet 7, the sheet 7 and the workpiece 1 are brought into close contact with each other. The workpiece 1 can therefore be fixed to the sheet 7 more strongly. When the workpiece fixing step is performed, the workpiece 1 is fixed to the sheet 7. After the workpiece fixing step and the sheet fixing step are performed, a frame unit 1c (see FIG. 6A) is formed in which the workpiece 1, the sheet 7, and the frame 9 are integral with each other. The workpiece 1 is carried into the processing apparatus and processed in a state of the frame unit 1c. Incidentally, when the workpiece 1 is desired to be processed from the undersurface 1b side, the top surface 1a side of the workpiece 1 is fixed to the sheet 7.

The processing step of the processing method according to the present embodiment will next be described. In the processing step, first, the frame unit 1c is carried into the processing apparatus. The processing apparatus is for example a cutting apparatus that cuts the workpiece 1 or a laser processing apparatus that forms a processed groove or an internal modified layer in the workpiece 1 by irradiating the workpiece 1 with a laser beam. The processing apparatus has the table 6 on which the frame unit 1c is placed. The table 6 for example has a projecting portion of a size corresponding to the opening 15a of the annular portion 11a and the opening 15b of the pressing portion 13a of the frame 9. The projecting portion has a flat top surface. When the frame unit 1c is disposed above the table 6 such that the opening 15a and the opening 15b above the projecting portion correspond to the projecting portion, and the frame 9 is lowered, the workpiece 1 is placed on a top surface of the table 6 with the sheet 7 interposed therebetween. The table 6 may for example have therewithin a suction mechanism that sucks the frame unit 1c. In this case, when the frame unit 1c is placed on the table 6, and the suction mechanism is actuated, the frame unit 1c is sucked and held by the table.

Next, in the processing step, the workpiece 1 is processed. FIG. 6B is a sectional view depicting a state in which an internal modified layer 25 is formed in the workpiece 1 by making a laser processing unit 8 condense a laser beam within the workpiece 1 along a planned dividing line 3 (see FIG. 1). The laser beam is a laser beam of a wavelength transmissible through the workpiece 1. In the vicinity of a condensing point of the laser beam within the workpiece 1, the workpiece 1 is modified by multiphoton absorption, and thus the internal modified layer 25 is formed. When the internal modified layer 25 is formed along the planned dividing lines 3, and cracks are extended from the internal modified layer 25 in the thickness direction of the workpiece 1, the workpiece 1 can be divided into each individual device chip.

The processing method according to the present embodiment can fix a workpiece even when the sheet 7 having no adhesive layer is used, and can fix the sheet 7 to the frame 9 even when an adhesive or the like is not used. Therefore, when each individual device chip formed is peeled off the sheet 7, the adhesive layer does not remain on the undersurface of the device chip, so that the occurrence of a defect in the device chip is suppressed. In addition, a glue layer, an adhesive, or the like does not remain on the frame 9, so that the frame 9 can be reused without the frame 9 being cleaned.

It is to be noted that in the foregoing embodiment, description has been made of a case where the workpiece 1 is fixed to the sheet 7 by using the pressing roller 4 in the workpiece fixing step. However, one mode of the present invention is not limited to this. For example, the workpiece 1 may be fixed to the sheet 7 by using a decompression chamber.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A workpiece processing method comprising:
a workpiece fixing step of fixing a workpiece to a sheet larger than the workpiece by a close contact force acting between the workpiece and the sheet;
a frame preparing step of preparing a frame including an annular portion having an opening of a diameter larger than the workpiece and smaller than the sheet and a pressing portion having an opening of a diameter larger than the workpiece and smaller than the sheet;
a sheet fixing step of fixing the sheet to the frame by sandwiching an outer circumferential portion of the sheet by the annular portion and the pressing portion after the frame preparing step and before or after the workpiece fixing step; and
a processing step of processing the workpiece after the workpiece fixing step and the sheet fixing step are performed.

2. The workpiece processing method according to claim 1, wherein
the frame has a magnet in the annular portion or the pressing portion, and
in the sheet fixing step, the sheet is sandwiched by a magnetic force acting between the annular portion and the pressing portion.

3. The workpiece processing method according to claim 1, wherein
the pressing portion has an outside diameter to fit into the opening of the annular portion, and
in the sheet fixing step, the pressing portion is fitted into the opening of the annular portion, and the sheet is sandwiched between an inner peripheral wall of the opening of the annular portion and an outer peripheral wall of the pressing portion.

4. The workpiece processing method according to claim 1, wherein
the frame further includes a fixing member, and
in the sheet fixing step, the annular portion and the pressing portion sandwiching the sheet are fixed by the fixing member.
